(19) United States
(12) Patent Application Publication
(10) Pub. No.: US 2008/0026550 A1
(43) Pub. Date: Jan. 31, 2008

(54) Laser doping of solid bodies using a linear-focussed laser beam and production of solar-cell emitters based on said method

(76) Inventors: Jurgen H. Werner, Stuttgart (DE); Jurgen Kohler, Waiblingen (DE); Ainhoa Esturo-Breton, Stuttgart (DE)

Correspondence Address: STRAUB & POKOTYLO, 620 TINTON AVENUE, BLDG. B, 2ND FLOOR, TINTON FALLS, NJ, 07724, US

(21) Appl. No.: 11/627,372

(22) Filed: Jan. 25, 2007

Related U.S. Application Data
(63) Continuation of application No. PCT/DE05/01280, filed on Jul. 21, 2005.

(30) Foreign Application Priority Data
Jul. 26, 2004 (DE) 102004036220.3-33

(51) Int. Cl. H01L 21/3215

(52) U.S. Cl. 438/535; 117/2

(57) ABSTRACT

In the laser doping method in accordance with the invention firstly a medium containing a dopant is brought into contact with a surface of the solid-state material. Then, by beaming with laser pulses, a region of the solid-state material below the surface contacted by the medium is melted so that the dopant diffuses into the melted region and recrystallizes during cooling of the melted region. The laser beam is focussed linearly on the solid-state material, the width of the linear focus being preferably smaller than 10 μm.

The present invention relates to a method of producing a doped region in solid-state material as it reads from the preamble of claim 1, it also relating to an apparatus for implementing the method. The invention relates furthermore to a method of producing an emitter region of a solar cell based on the method in accordance with the invention. The invention relates in addition to a method of producing an ohmic contact between a semiconductor and a metal.

In commercial fabrication of single-crystal or multi-crystal silicon solar cells the solar cell emitter is produced by a high-temperature step in production, followed by diffusion of the dopant, generally phosphor, in a diffusion oven at a temperature of approx. 1000 K. The time needed for this is roughly 30 minutes. Thus, conventional fabrication of solar cell emitters by diffusion in a diffusion oven is energy and time consuming.

In addition this, because of the lengthy process time for emitter diffusion in the conventional diffusion process, fabrication can be implemented only in batches in a production system. Low cost fabrication of solar cells requires, however, simple and fast individual steps in the process suitable for integrating in a continual, i.e. inline production process. Fabrication of solar cell emitters by diffusion in a diffusion oven fails to satisfy these requirements.

Known from U.S. Pat. No. 5,918,140 is a method for laser doping semiconductors by first depositing a thin layer of a material containing a dopant on a semiconductor surface followed by exposure of the semiconductor surface to a pulsed laser beam, the energy of the laser pulses being absorbed and converted into thermal energy in the region of the interface between the semiconductor surface and the deposited dopant layer. This results in the upper region of the semiconductor melting and thus causing the dopant atoms to be incorporated into the molten region as diffused during melting. During and following the fall time of the laser pulse the molten region of the semiconductor recrystallizes, whereby the dopant atoms are incorporated in the crystal lattice. This makes it possible in particular to produce near-surface doped regions featuring a high dopant concentration in solid-state material. Hitherto it was, however, not possible to implement laser doping of a semiconductor such as silicon such that the silicon is able to recrystallize in a melted surface layer roughly 1 μm or less thick without defects. In tests, doped regions were produced in silicon using commercially available laser processing system. The result was solar cell emitters of very poor quality with in particular very low values for the no-lad voltage and efficiency of the solar cells. TEM analysis showed in addition that the solar cell emitters suffer damage particularly by a high dislocation density.

It is thus an object of the present invention to define methods of producing a doped region in solid-state material by means of laser doping, in now making it possible to achieve a high freedom from defects of the solid-state material in the doped region, or by which in another way the conventional methods can be enhanced as regards furnishing the dopant layer, achieving high dopant concentrations or boosting the efficiency in laser power beaming.

This object is achieved by the characterizing features of claim 1 and of the further independent claims. Advantageous further embodiments and aspects form the subject matter of the sub-claims. A method of producing an emitter region of a solar cell by means of the method in accordance with the invention is likewise defined. Also defined is a method of producing an ohmic contact between a semiconductor and a metal by means of the method in accordance with the invention. Defined furthermore is an apparatus for implementing the methods in accordance with the invention.

In the methods in accordance with the invention for producing a doped region in solid-state material firstly a medium containing a dopant is brought into contact with a surface of the solid-state material. Then, by beaming with laser pulses, a region of the solid-state material below the surface contacted by the medium is melted so that the dopant diffuses into the melted region and recrystallizes during cooling of the melted region.

One aspect substantial to a method in accordance with the invention is that the laser beam is focussed linearly on the solid-state material, the width of the linear focus being selected smaller than 10 μm. For example, the focus width may be in the range 5 μm to 10 μm. However, the focus width may even amount to roughly 5 μm or less.

Tests have since confirmed that by providing a linear focus for the laser doping method recrystallized doped regions having a high freedom from defects can now be produced. This is achieved by the method in accordance with the invention without needing to employ a high-temperature process and without the necessity of lengthy process times. Instead, the method in accordance with the invention represents a low-temperature method of doping solid-state material producing doped regions of high crystallinity and freedom from defects.

The method in accordance with the invention thus now makes it possible to replace batch processing of the semiconductor wafers in high-temperature ovens by an inline process with more effective logistics for direct integration in the fabrication of electronic components such as solar cells.

In the tests as implemented the laser beam was formed to a line 5 μm wide and several 100 μm long, the length of the linear focus generally being preferably in a range of 100 μm to 10 mm.

In the method in accordance with the invention the extent of the depth of the regions to be doped can be defined by suitably selecting the wavelength of the laser. This is done by selecting a wavelength such that the absorption length or depth of penetration of the laser beam in the solid-state material corresponds to the desired extent of the depth in the doped region. For solar cell emitters this depth is selected to be 1 μm or less. When the solid-state material is the semiconductor silicon, the wavelength of the laser beam should accordingly be 600 nm or less.

In addition, when a certain extent in the depth of the doped region is desired the pulse length should be selected so that the thermal diffusion length of the dopant atoms in the melted solid-state material is of a magnitude in the range of the desired extent in the depth. When the solid-state material is the semiconductor silicon and the desired extent in the depth is 1 μm the pulse length should be below 100 ns, preferably below 50 ns.

Normally a region is to be doped whose lateral extents in at least one direction are greater than the linear focus so that the beam pencil needs to be scanned over the solid-state material, producing a relative motion between the solid-state material and the beam pencil which is aligned perpendicular to the line of the linear focus. Preferably the solid-state material is mounted on a X-Y linear stage and the laser beam maintained stationary. However, it is just as possible to provide for the solid-state material remaining stationary and the optical system of the laser beam configured to scan the laser beam over the solid-state material.

The material containing the dopant may be deposited on the interface in the form of a liquid or solid coating by spin coating or by screen or film printing. However, it is just as possible to provide for the medium being gaseous and bringing it into contact with the surface of the solid-state material directly.

One aspect substantial to a further method in accordance with the invention is that the medium containing the dopant is deposited in the form of a solid coating on the solid-state material by sputtering, the laser beam not necessarily needing to be focussed linear in later melting. It may be provided for that the medium is first deposited on a starting substrate before then being sputtered therefrom in a first step in sputtering and deposited on an intertarget and then in conclusion sputtered from the intertarget in a second step in sputtering and deposited on the solid-state material to be doped.

In this arrangement the starting substrate like the intertarget may involve silicon in each case as substrate and wafer. The medium may substantially or fully consist of the dopant itself or, for example, deposited as a powder on the starting substrate. Thus, particularly the dopant elements as usually provided, i.e. phosphor, arsenic, antimony, boron, aluminum, gallium, indium, tantalum or titanium may be firstly deposited as a powder on a silicon wafer before being sputtered from the silicon wafer on to the intertarget. The layer deposited in conclusion from the intertarget on to the solid-state material to be doped may thus comprise to more than 90% the dopant, since in sputtering only slight amounts of the substrate silicon are included in the first step in sputtering. Thus, in such a method only a very thin dopant layer, for example just a few nanometers thick, on the solid-state material to be doped to produce a very high dopant concentration, for example as high as 10²²/cm³ in the solid-state material.

It is understood that solid-state material to be doped in the present context of this application may mean a semiconductor itself to be doped, but it may also be understood that the solid-state material is a main material constituting the semiconductor material as such to be doped and containing an interlayer deposited on a surface of the main material, whereby in accordance with a further method in accordance with the invention the medium is deposited on the interlayer. In this arrangement it is not a mandatory requirement that in subsequent laser beam doping the laser beam is linear focussed. One such aspect is the case, for example, when an interlayer acting as an anti-reflex layer for the laser beam is deposited on the semiconductor material. The anti-reflex layer ensures that the full beam pencil of the laser beam is exploited in use for melting the surface region of the semiconductor material located under the interlayer. The dopant can then be diffused during the melting by the interlayer into the semiconductor material. Despite the interlayer high dopant concentrations can be produced in the semiconductor material in this way, since particularly by the aforementioned sputtering very high dopant concentrations can be produced previously on the interlayer. As a result of the high dopant gradient the dopant diffuses also through the interlayer with high velocity.

As an alternative, or in addition thereto, the interlayer may be configured as a passivation layer for passivating the surface of the semiconductor material.

In particular, the interlayer may contain silicon nitride, silicon dioxide or amorphous silicon or be based on one of these materials.

The interlayer may also be produced by sputtering. Particularly when the dopant layer is produced by sputtering, dopant layer and interlayer can be produced in one and the same sputter system.

The method in accordance with the invention can be put to use particularly for producing an emitter region of a solar cell by it doping regions of a semiconductor surface employed as solar cell emitters.

Furthermore, the method in accordance with the invention can be put to use for producing an ohmic contact between a semiconductor and a metal by a doped region being produced in a semiconductor by the method in accordance with the invention and subsequently a metallized layer being deposited on the doped region in thus enabling ohmic contacts with a very low contact resistance to be produced on both p- and n-type wafers. The methods as described in this application also permit producing point contacts or strip contacts.

The invention also relates to an apparatus for implementing the method in accordance with the invention comprising a pulsed laser beam source, a cylinder lens for producing the linear focus and an objective for imaging the linear focus reduced in size on the surface of the solid-state material.

This apparatus comprises preferably an autofocus device which measures the spacing of the solid-state material surface from a reference point and regulates the spacing between objective and solid-state material surface such that the focal position remains within the depth of focus on the solid-state material surface in ensuring that the focal position is maintained within the depth of focus on the wafer surface despite the surface being curved or rough.

Example embodiments of the method in accordance with the invention and an apparatus for its implementation will now be detailed with reference to the FIGs. in which:

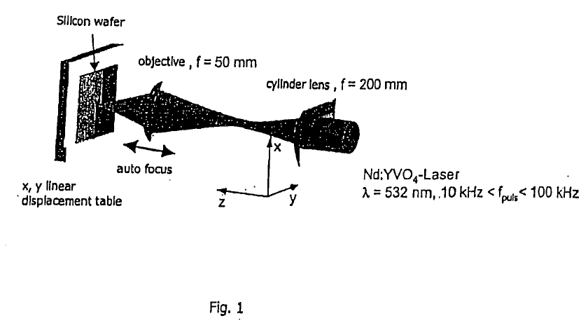

FIG. 1 is an illustration of an example embodiment of an apparatus for implementing the method in accordance with the invention;

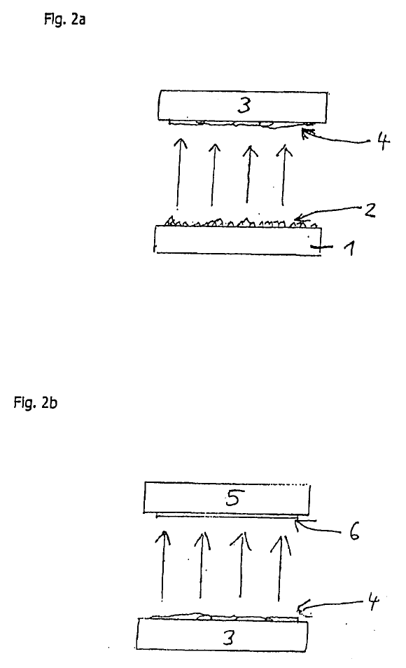

FIG. 2a, b is an illustration of an example embodiment for implementing the method in accordance with the invention in using a two-stage sputtering method;

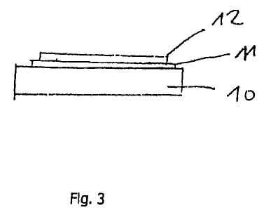

FIG. 3 is an illustration of an example embodiment for implementing the method in accordance with the invention with an additional anti-reflex layer on the semiconductor material.

Referring now to FIG. 1 there is illustrated an apparatus in which the source of the laser beam in this case is a Q-switched Nd:YVO4 laser which by doubling the frequency emits a laser beam having a wavelength of λ=532 nm. The pulse frequency is typically in the range 10 kHz to 100 kHz. When laser doping silicon the optimum pulse energy density is in the range 2 to 6 J/cm⁻².

The laser beam is then—where necessary after widening—focussed by a cylinder lens to produce a linear focus. In the present case the cylinder lens has a focal length of f=200 mm.

In conclusion, the laser beam is imaged by an objective on the silicon wafer, the objective having in the example embodiment a focal length of f=50 mm. The objective images the linear focus reduced in size on the silicon wafer. Here, it needs to be made sure that the focus always remains on the wafer surface within the depth of focus of the imaging optics even with curved or rough surfaces. This is achievable by an autofocus device which continually measures the spacing of the wafer surface from a reference point and corrects the spacing between objective and silicon wafer. In the example embodiment as shown the position of the objective is corrected by shifting it on the centerline of the beam, although it may just as well be provided for that the position of the silicon wafer is shifted on the centerline of the beam for correction.

The silicon wafer is mounted on an X-Y linear stage, the X-Y plane being perpendicular to the laser beam. By shifting the silicon wafer relative to the impinging beam pencil a larger region can be scanned on the silicon wafer.

In tests for fabricating solar cell emitters a commercially available phosphated dopant liquid was applied to the silicon wafer by a spin coater. Doping is implemented by one or more laser pulses fleetingly melting the wafer surface down to a depth of 1 μm or less and atoms of phosphor from the dopant liquid gaining access into the molten silicon. After cooling and solidification of the melt a highly doped n-type emitter region is completed.

Boron-doped p+-type emitters on a Si n-type wafer have also already been processed by the method in accordance with the invention.

The beam pencil is guided preferably continually at the predefined velocity over the wafer surface, after having established how many laser pulses are needed for each region of the surface to achieve a satisfactory degree of doping. From this number and the pulse frequency the scanning velocity can then be determined. Preferably the scanning velocity is in a range 0.1 to 0.5 m/s. However, as an alternative thereto it may also be provided for to shift the stage in discrete steps substantially corresponding to the focus width. At each accessed point the silicon wafer is beamed stationary with a predefined number of laser pulses and subsequently the linear focus is positioned, without beaming with laser pulses, perpendicular to the orientation of the line at a next point.

When using a 30 W laser system a throughput of approx. 10 cm²/s is achievable.

Referring now to FIGS. 2a, b there is illustrated a variant of the method in accordance with the invention in which the medium is deposited in the form of a solid coating by a two-stage sputter process on the solid-state material to be doped. Firstly, a dopant 2, for example pure phosphor powder is deposited on a silicon wafer 1 as the starting substrate. Then, in FIG. 2a in a first step in sputtering the powder dopant 2 is sputtered and deposited as such on an intertarget 3 formed likewise by a silicon wafer and deposited as a dopant layer 4 on this intertarget 3. This firstly achieves that a contiguous dopant layer 4 is provided which may, for example, comprise a dopant concentration exceeding 90%. Apart from the dopant itself, for instance phosphor, the dopant layer may also contain silicon which is additionally removed from the silicon wafer 1 in the first step in sputtering.

In a second step in sputtering as shown in FIG. 2b the dopant layer 4 is sputtered and deposited as such on the actual solid-state material 5 to be doped in the form of a second dopant layer 6. As compared to the dopant layer 4 this dopant layer 6 features an even greater homogenity in its material composition so that in subsequent laser beam doping a highly homogenous doping density is achievable in the solid-state material 5. The dopant layer 6 may be just a few nm thick, for example, 1-10 nm.

After this, the laser beam is focussed on the solid-state material 5 with the deposited dopant layer and as such briefly melted in a surface region, noting that the focus must not necessarily be a linear focus. The dopant of the dopant layer 6 then diffuses into the melted near-surface region of the solid-state material 5 and is incorporated in the lattice structure of the solid-state material on recrystallization.

Referring now to FIG. 3 there is illustrated a further variant of the method in accordance with the invention in which an anti-reflex layer 11 is deposited on a semiconductor material such as for instance a silicon wafer 10 above a region of the semiconductor material 10 to be doped. The anti-reflex layer 11 is configured so that the laser beam later used for melting experiences a reflection coefficient as low as possible so that the light capacity thereof is beamed into the semiconductor material 10 practically completely.

A medium containing the dopant is then deposited on the anti-reflex layer 11. This medium may consist of the dopant itself, for example, and be deposited by sputtering on the anti-reflex layer 11. Using particularly, as described above, a two-stage sputtering process dopants such as phosphor or the like can be deposited in high concentration on the anti-reflex layer 11. The anti-reflex layer 11 can likewise be produced by sputtering, preferably in one and the same sputter chamber.

The laser beam is then focussed onto the semiconductor material 10 and melted in a surface region as such briefly, for which a linear focus is not necessarily needed. The dopant then diffuses through the anti-reflex layer 11 into the melted near-surface region of the semiconductor material 10 and is incorporated in the lattice structure on recrystallization.

For particularly efficiency solar cells multistage emitters are known which by methods as known hitherto also necessitate further high-temperature processes as well as photolithographic patterning. By the method in accordance with the invention in making use of a laser having a relatively high pulse frequency lateral patterning of the dopant concentration can be additionally and simultaneously achieved for producing multistage emitters.

With the aid of the method in accordance with the invention (or as such alone) the so-called back surface field can also be produced which reduces the recombination of back surface minority carriers. The process is as described above but depositing boronized dopant paste on the back surface of the p-type wafer and then beaming the surface with the laser.

1-21. (canceled)

22. A method of producing a doped region in solid-state material, the method comprising:
depositing a medium containing a dopant to place the medium in contact with a surface of the solid-state material;
linearly focusing a laser beam onto the solid-state material; and
beaming with laser pulses, a region of the solid state material below the surface contacted by the medium to melt said medium and allow the dopant to diffuse into the melted region and recrystallize during cooling of the melted region.

23. The method of claim 22, wherein the width of the linear focus of said laser beam is smaller than 10 μm.

24. The method of claim 22, wherein the length of the linear focus of said laser beam is in the range 100 μm to 10 mm.

25. The method of any of claims 22, 23 or 24 wherein the wavelength of the laser is selected such that the absorption length of the laser beam in the solid-state material corresponds to a predefined length.

26. The method of claim 25, wherein the predefined length is 1 μm.

27. The method as set forth in claim 25, wherein the solid-state material is silicon and the laser beam has a wavelength which is below 600 nm.

28. The method as set forth in any of claims 22, 23, or 24, wherein a pulse length of said laser pulses is selected such that the thermal diffusion length of the dopant atoms in the melted solid-state material corresponds to a predefined length.

29. The method of claim 28, wherein the predefined length 1 μm.

30. The method as set forth in claim 28 wherein the solid-state material is silicon and the pulse length is below 100 ns.

31. The method of claim 30, wherein the pulse length is below 50 ns.

32. The method of any of claims 22, 23, or 24 wherein a beam pencil is scanned over the solid-state material producing a relative motion between the solid-state material and the beam pencil.

33. The method of any of claims 22, 23 or 24, wherein the medium is in the form of one of i) a liquid and ii) a solid coating; and
wherein depositing the medium includes one of: spin coating, screen printing and film printing.

34. The method of any of claims 22, 23 or 24, wherein the medium is a solid coating (6) and wherein depositing said medium includes:
sputtering the medium onto the solid-state material.

35. The method as set forth in claim 34, wherein the medium is first deposited on a starting substrate (1) before then being sputtered therefrom in a first step in sputtering and deposited on an intertarget (3) and then sputtered from the intertarget (3) in a second step in sputtering and deposited on the solid-state material (5) to be doped.

36. The method as set forth in claim 35, wherein the intertarget (3) is a silicon substrate.

37. The method as set forth in claim 35, wherein the medium consists of the dopant itself and is deposited in the form of a powder on the starting substrate.

38. The method as set forth in any of claims 22, 23 or 24, wherein the solid state-material contains a main material and an interlayer (11) deposited on a surface of the main material (10) and the medium is deposited on the interlayer (11).

39. The method as set forth in claim 38, wherein the interlayer (11) is a passivation layer.

40. The method of claim 38 wherein the interlayer (11) acts as anti-reflex layer for the laser beam.

41. The method of claim 38, wherein the interlayer (11) includes one of: silicon nitride, silicon dioxide and amorphous silicon. based on one of these materials.

42. The method of claim 38, wherein the interlayer (11) is based on one of: silicon nitride, silicon dioxide and amorphous silicon.

43. The method of claim 22,
wherein said solid state material is a semiconductor and
wherein said method is a method of producing an emitter region of a solar cell.

44. The method of claim 22, wherein said method is a method of producing an ohmic contact between a semiconductor and a metal and a doped region in a solar cell, the method further comprising, after performing the steps of claim 22, depositing a metallized layer on the doped region.

45. An apparatus for implementing the method of claim 22, the apparatus comprising:
a pulsed laser beam source, a cylinder lens for producing the linear focus and an objective for imaging the linear focus reduced in size on the surface of the solid-state material.

46. The apparatus as set forth in claim 45, further comprising an autofocus device which measures the spacing of the solid-state material surface from a reference point and regulates the spacing between objective and solid-state material surface such that the focal position remains within the depth of focus on the solid-state material surface.
